(19) United States
(12) Patent Application Publication
(10) Pub. No.: US 2015/0364708 A1
(43) Pub. Date: Dec. 17, 2015

(54) PLASMONIC ORGANIC PHOTOVOLTAIC CELL USING INDUCED DIPOLE POLYMER-METAL NANOPARTICLE HYBRID AND FABRICATION PROCESS THEREOF

(71) Applicant: KOREA INSTITUTE OF SCIENCE AND TECHNOLOGY, Seoul (KR)

(72) Inventors: Dong Ick SON, Jeollabuk-do (KR); Soo Min KIM, Daegu (KR); Tae Wook KIM, Gyeonggi-do (KR); Su Kang BAE, Gyeongsangnam-do (KR); Sang Hyun LEE, Jeollabuk-do (KR); Byung Joon MOON, Gwangju (KR); Su Yeon SON, Jeollabuk-do (KR); Kyu Seung LEE, Jeollabuk-do (KR)

(21) Appl. No.: 14/458,412

(22) Filed: Aug. 13, 2014

(30) Foreign Application Priority Data
Jun. 17, 2014 (KR) 10-2014-0073537

(51) Int. Cl. H01L 51/44; H01L 51/42

(52) U.S. Cl. CPC H01L 51/44; H01L 51/4206; H01L 51/4253; H01L 51/442; H01L 51/0003

(57) ABSTRACT

The present invention relates to a high-efficiency organic photovoltaic cell using surface plasmon effect of an induced dipole polymer-metal nanoparticle hybrid and a method for fabricating the same. More particularly, it relates to a high-efficiency organic photovoltaic cell whose photoelectric efficiency is maximized by depositing an induced dipole polymer-metal nanoparticle hybrid in or on a hole injection layer, thereby enhancing surface plasmonic properties, and a method for fabricating the same.

### CROSS-REFERENCE TO RELATED APPLICATIONS

This application claims priority under 35 U.S.C. §119 to Korean Patent Application No. 10-2014-0073537, filed on Jun. 17, 2014, in the Korean Intellectual Property Office, the disclosure of which is incorporated herein by reference in its entirety.

### BACKGROUND

1. (a) Technical Field

The present invention relates to a high-efficiency organic photovoltaic cell using surface plasmon effect of an induced dipole polymer-metal nanoparticle hybrid and a method for fabricating the same. More particularly, it relates to a high-efficiency organic photovoltaic cell whose photoelectric efficiency is maximized by depositing an induced dipole polymer-metal nanoparticle hybrid in or on a hole injection layer, thereby enhancing surface plasmonic properties, and a method for fabricating the same.

2. (b) Background Art

An organic photovoltaic cell included in an organic optoelectronic device is drawing attentions as a next-generation energy source due to relative easiness in fabrication, environment friendliness and semi-permanent operation life. In particular, the organic photovoltaic cell is also useful as a light source for ecofriendly illumination due to superior luminous efficiency.

Various studies are under way on device structure and modification to improve the efficiency of the organic optoelectronic device including the organic photovoltaic cell. For example, for improvement of the photoelectric efficiency of the organic photovoltaic cell, a method of depositing metal nanoparticles in or on a hole injection layer, thereby transporting electrons and holes to an electrode collector layer and improving photoconversion efficiency using surface plasmonic properties, is known.

Korean Patent Publication No. 2013-114465 discloses an organic thin-film solar cell with high efficiency using surface plasmon resonance, which is prepared by depositing a nanoparticle layer of metal nanoparticles.

As another type of organic solar cell, an organic photovoltaic cell using an induced dipole polymer has been developed. For example, researches are actively under way on a structure wherein a thin film of zinc oxide (ZnO) is deposited on a transparent electrode and induced dipole polymers polyethylenimine ethoxylated (PEIE) and polyethylenimine (PEI) are used to efficiently transport electrons and holes to an electrode collector layer based on the flat band shift mechanism, thereby improving photoconversion efficiency.

In S. Woo et al., 8.9% Single-Stack Inverted Polymer Solar Cells with Electron-Rich Polymer Nanolayer-Modified Inorganic Electron-Collecting Buffer Layers, Adv. Energy Mater., 1301692 (2014), a bulk heterojunction thin film of poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]] (PTB7) and [6,6]-phenyl-C₇₁butyric acid methyl ester (PC₇₁BM) is deposited as an active layer and a nanosized PEI layer is deposited on a transparent electrode to facilitate charge transport.

In A. K. K. Kyaw et al., Efficient Solution-Processed Small-Molecule Solar Cells with Inverted Structure, Adv. Mater., 25, 2397 (2013), a bulk heterojunction thin film of low-molecular-weight 7,7′-(4,4-bis(2-ethylhexyl)-4H-silolo[3,2-b:4,5-b′]dithiophene-2,6-diyl)bis(6-fluoro-4-(5′-hexyl-[2,2′-bithiophen]-5-yl)benzo[c][1,2,5]thiadiazole) (p-DTS(FBTTh₂)₂) and PC₇₁BM is deposited on a PEIE layer to improve efficiency.

And, T. H. Lee et al., Replacing the metal oxide layer with a polymer surface modifier for high-performance inverted polymer solar cells, RSC. Adv., 4, 4791 (2014) reports a high-efficiency organic photovoltaic cell device wherein PEIE and zinc oxide are formed in multiple layers and the polymers PTB7 and P3HT are mixed with PC₇₁BM.

Although there has been some achievement in photoelectric efficiency, there remains a lot to be improved.

Korean Patent Registration No. 10-1112676 proposes fabrication of a large-area organic photovoltaic cell exhibiting high energy conversion efficiency through improvement in plasmon resonance effect and conductivity by introducing metal nanoparticles to an organic/inorganic hybrid buffer layer. Korean Patent Publication No. 2010-97471, which relates to a metal-polymer hybrid nanoparticle, a method for manufacturing the same and a light-emitting device and a solar cell using the same, proposes mixing a metal nanoparticle with an organic light-emitting polymer to improve energy transmission between the nanoparticle and the organic light-emitting polymer through surface plasmon resonance based on the difference in their energy levels. And, Korean Patent Publication No. 2013-71191 presents a method for manufacturing an optoelectronic device including a metal layer, in order to provide improved device efficiency through surface plasmon resonance of metal nanoparticles, by introducing a metal layer including metal nanoparticles into an organic optoelectronic device, the metal layer being formed by coating a mixture of a block copolymer and a metal nanoparticle and then removing the block copolymer.

Besides, Ji Hwang Lee, et al., Organic Electronics, 2009, Vol. 10, No. 3, pp. 416-420, which relates to a solar cell including multiple layers containing gold nanorods on an ITO substrate, presents a high-efficiency organic photovoltaic cell using the surface plasmon effect of the gold nanorods using a PEI polymer as the material of the multiple layers.

As described, many methods of fabricating a solar cell with improved energy efficiency through the surface plasmon resonance effect of metal nanoparticles have been proposed.

Although they improve photoelectric efficiency through the plasmon effect using metal particles and polymers, they involve complicated processes or have difficulty in commercialization and need further improvement in efficiency. As such, although solar cell devices using induced dipole polymers are studied a lot recently, further improvement in efficiency is impossible because of structural limitation.

### REFERENCES OF THE RELATED ART

### Patent Documents

(Patent document 1) Korean Patent Publication No. 2013-114465.

(Patent document 2) Korean Patent Registration No. 10-1112676.

(Patent document 3) Korean Patent Publication No. 2010-97471.

(Patent document 4) Korean Patent Publication No. 2013-71191.

### Non-Patent Documents

(Non-patent document 1) S. Woo et al., 8.9% Single-Stack Inverted Polymer Solar Cells with Electron-Rich Polymer Nanolayer-Modified Inorganic Electron-Collecting Buffer Layers, Adv. Energy. Mater., 1301692 (2014).

(Non-patent document 2) A. K. K. Kyaw et al., Efficient Solution-Processed Small-Molecule Solar Cells with Inverted Structure, Adv. Mater., 25, 2397 (2013).

(Non-patent document 3) T. H. Lee et al., Replacing the metal oxide layer with a polymer surface modifier for high-performance inverted polymer solar cells, RSC Adv., 4, 4791 (2014).

(Non-patent document 4) Ji Hwang Lee, et al., Organic Electronics, 2009, Vol. 10, No. 3, pp. 416-420.

### SUMMARY

The present invention aims at providing a high-efficiency organic photovoltaic cell with maximized photoelectric efficiency. Through consistent researches, the inventors of the present invention have found out that the photoelectric efficiency of a solar cell device can be maximized through enhanced surface plasmonic properties by depositing an induced dipole polymer and a metal nanoparticle in or on a hole injection layer.

The present invention is directed to providing a high-efficiency organic photovoltaic cell with maximized surface plasmon effect by introducing an induced dipole polymer-metal nanoparticle hybrid.

The present invention is also directed to providing a method for fabricating a high-efficiency organic photovoltaic cell via a relatively simple method using an induced dipole polymer and a metal nanoparticle.

In an aspect, the present invention provides an organic photovoltaic cell having a charge transport layer including an induced dipole polymer and a metal nanoparticle exhibiting surface plasmon property at a weight ratio from 1:0.1 to 1:1 on a conductive transparent electrode.

In another aspect, the present invention provides a method for fabricating an organic photovoltaic cell, including:

mixing an induced dipole polymer and a metal nanoparticle at a weight ratio from 1:0.1 to 1:1;

coating the resulting mixture of the induced dipole polymer and the metal nanoparticle on an ITO substrate;

coating a polymer solar cell material on the mixture of the induced dipole polymer and the metal nanoparticle;

coating molybdenum oxide (MoO₃) on the polymer solar cell material; and forming a metal electrode.

In accordance with the present invention, the photoconversion efficiency of a solar cell device can be maximized due to improved transport of electrons and holes to an electrode collector layer by through enhanced surface plasmon properties by using a mixture of an induced dipole polymer and a metal nanoparticle.

The organic photovoltaic cell of the present invention is industrially applicable to various fields owing to easy fabrication and very superior photoelectric efficiency. In particular, since the organic semiconductor material can be used in small amount, the materials cost can be greatly decreased as compared to the existing inorganic-based solar cells.

In addition, the present invention can be applied to fabrication of inexpensive large-area, thin-film devices and can reduce processing cost because fabrication of flexible devices is possible via a roll-to-roll process.

### BRIEF DESCRIPTION OF THE DRAWINGS

FIG. 1 schematically shows a cross-sectional structure of a solar cell device prepared according to the method described in Examples 1-3 in which a silver nanoparticle is mixed. (a) shows the structure of an existing solar cell device wherein only PEIE is used without using a silver nanoparticle and (b) shows the structure of a solar cell fabricated in Examples 1-3.

FIG. 2 briefly describes a process of forming layers in fabricating a solar cell according to an exemplary embodiment of the present invention.

FIG. 3 schematically describes a mechanism by which a plasmon is formed from an induced dipole polymer-metal nanoparticle hybrid layer of an organic photovoltaic cell fabricated according to an exemplary embodiment of the present invention.

FIG. 4 shows a band diagram of an organic photovoltaic cell device fabricated according to an exemplary embodiment of the present invention. (a) shows a band diagram of an existing solar cell having a single layer of an induced dipole polymer and (b) shows a band diagram of a solar cell device fabricated according to an exemplary embodiment of the present invention wherein an induced dipole polymer-metal nanoparticle hybrid is used.

FIG. 5 compares photocurrent in organic photovoltaic cell devices fabricated in Examples 1-7 according to the present invention. (a) compares the current density-voltage (J-V) characteristics of the organic photovoltaic cells fabricated in Examples 1-3 using a silver nanoparticle and (b) compares the current density-voltage (J-V) characteristics of the organic photovoltaic cells fabricated in Examples 4-7 using a silver nanowire.

### DETAILED DESCRIPTION

Hereinafter, the present invention is described in further detail using specific exemplary embodiments.

The terminology used herein is for the purpose of describing particular embodiments only and is not intended to be limiting of the exemplary embodiments. As used herein, singular expressions are intended to include plural forms as well, unless the context clearly indicates otherwise. It will be further understood that the terms “comprise” or “have”, when used in this specification, specify the presence of stated features, integers, steps, operations, elements, and/or components, but do not preclude the presence or addition of one or more other features, integers, steps, operations, elements, components, and/or groups thereof.

The present invention relates to an organic photovoltaic cell of a novel structure, which has a charge transport layer wherein an induced dipole polymer having a large slope in the flat band shift and thus facilitating charge transport and a metal nanoparticle are mixed. Since a surface plasmon is generated in the charge transport layer, it allows more efficient transport of electrons and holes to an electrode collector layer as compared to an existing solar cell device using a metal nanoparticle and thus can maximize photoconversion efficiency.

The present invention provides an organic photovoltaic cell including a charge transport layer and an electrode collector layer on a conductive transparent electrode, wherein the charge transport layer includes an induced dipole polymer and a metal nanoparticle exhibiting surface plasmon property at a weight ratio from 1:0.1 to 1:1 on a conductive transparent electrode.

In an exemplary embodiment of the present invention, the induced dipole polymer may be polyethylenimine (PEI) or polyethylenimine-ethoxylated (PEIE).

In an exemplary embodiment of the present invention, the metal nanoparticle may be one or more meal selected from Ag, Pt and Au.

In an exemplary embodiment of the present invention, the electrode collector layer may be formed from lamination of an energy-converting polymer.

In the present invention, the induced dipole polymer and the metal nanoparticle are mixed at a weight ratio from 1:0.1 to 1:1. If the metal nanoparticle is included in excess amount, induced dipole effect weakens greatly at the interface with ITO because of the decreased ratio of the induced dipole polymer in the resulting hybrid. This leads to decreased band bending at the interface between the hybrid and ITO, thereby limiting carrier mobility. In addition, since the excess metal nanoparticle forms a nonuniform surface on the hybrid, interfacial resistance (contact resistance) and leakage current are increased and improvement in efficiency cannot be expected.

In an exemplary embodiment of the present invention, the hybrid prepared from the mixing of the induced dipole polymer and the metal nanoparticle exhibits enhanced plasmonic property because of the induced dipole polymer having a large slope in the flat band shift which improves charge transport by the metal nanoparticle. As a result, electrons and holes can be more efficiently transported to the electrode collector layer and the photoelectric efficiency of the solar cell device can be maximized.

The operation mechanism of the organic photovoltaic cell according to the present invention is as follows.

Upon photoexcitation, an exciton which is a pair of an electron and a hole is formed in a hole acceptor. The exciton is separated into an electron and a hole at the interface between the hole acceptor and an electron acceptor due to the difference in electron affinity of the two materials. The separated electron moves toward a negative electrode through the electron acceptor and the hole moves toward a positive electrode through the hole acceptor due to built-in electric field. Since the electron hops between the electron acceptors, its speed is low and the photocurrent is limited.

Therefore, in the organic photovoltaic cell according to the present invention, an electron transport layer is constructed with a hybrid of a metal nanoparticle and an induced dipole polymer. In the electron transport layer, surface plasmon resonance occurs at the interface between the induced dipole polymer and the metal nanoparticle and energy efficiency is enhanced due to excitation of electron-hole (exciton) in the active layer through dispersion occurring between the metal nanoparticles. The surface plasmon (SP) is also called a surface plasmon polariton (SPP) or a plasmon surface polariton (PSP). The surface plasmon generally refers to collective oscillations of conduction band electrons propagating across an interface of a metal having a negative dielectric function (∈′<0) and a medium having a positive value (∈′>0). As a result of interaction with light (more specifically, an electromagnetic wave), the excited surface plasmon has a larger intensity than that of the incident light and has properties of an evanescent wave whose intensity decreases exponentially with increasing distance from the interface. That is to say, the ‘surface plasmon resonance (SPR)’ phenomenon can be defined as a unique phenomenon caused as a result of interaction between light (i.e., a photon) and a nanosized noble metal nanoparticle.

Since the organic photovoltaic cell according to the present invention exhibits increased photocurrent as compared to the existing solar cell and includes a nanosized hybrid layer wherein the two components are mixed, holes and electrons can be efficiently transported from the metal nanoparticle to the electrode collector layer due to the flat band shift mechanism owing to the induced dipole polymer having a large slope. As a result, the transport of holes and electrons to the electrode collector layer can be maximized and also the photoconversion efficiency can be maximized.

In accordance with the present invention, the high-efficiency organic photovoltaic cell using the surface plasmon effect of the induced dipole polymer-metal nanoparticle hybrid is fabricated by hybridizing and coating an induced dipole polymer and a metal nanoparticle and then coating a polymer solar cell material and molybdenum oxide (MoO₃) and forming a metal electrode thereon.

In an exemplary embodiment of the present invention, the metal nanoparticle may have a diameter smaller than 15 nm, more specifically 0.1-10 nm. The metal nanoparticle includes a metal nanowire. The metal nanowire may have a length smaller than 100 nm, more specifically 1-80 nm.

In an exemplary embodiment of the present invention, the induced dipole polymer and the metal nanoparticle may be mixed at a weight ratio of 1:0.1-1, more specifically 1:0.1-0.5.

In an exemplary embodiment of the present invention, an electron transport layer is formed by coating the resulting mixture on a thin ITO film specifically by spin coating and drying the same. Specifically, the electron transport layer may be formed by spin coating at 1500-6000 rpm, more specifically at 2000-5000 rpm.

In an exemplary embodiment of the present invention, the polymer solar cell material is coated on the electron transport layer as an active layer. The polymer solar cell material may be a mixture of one or more selected from P3HT, PTB7 and PCDTBT and one or more selected from PC₆₀BM and PC₇₀BM.

Then, the organic photovoltaic cell may be fabricated by coating molybdenum oxide (MoO₃) on the polymer solar cell material, for example, by deposition and then forming a metal electrode, e.g., a silver (Ag) electrode.

The high-efficiency organic photovoltaic cell using the surface plasmon effect of the induced dipole polymer-metal nanoparticle hybrid fabricated according to the present invention may be applicable specifically to fabrication of inexpensive thin-film or large-area devices, flexible devices, etc. In this case, up to about 50% or more improvement in photoconversion efficiency may be achieved.

### EXAMPLES

Hereinafter, the present invention is described in further detail through examples. However, the present invention is not limited by the examples.

### Preparation Example 1

### Preparation of Silver Nanoparticle

First, 2 mM sodium borohydride (NaBH₄) solution is prepared by adding 2.3 mg of sodium borohydride (NaBH₄) to 30 mL of triply distilled water. And, a silver nitrate aqueous solution is prepared by adding 1.7 mg of silver nitrate (AgNO₃) to 10 mL of triply distilled water. The previously prepared sodium borohydride (NaBH₄) solution is added to an Erlenmeyer flask and stirred at low temperature with the Erlenmeyer flask in an ice bath. While stirring the sodium borohydride (NaBH₄) solution, the previously prepared silver nitrate (AgNO₃) solution is added dropwise with one drop per second to the sodium borohydride solution. As the amount of the silver nitrate (AgNO₃) aqueous solution increases, the color of the solution changes. About 10 seconds later, the solution exhibits light yellow color. As the amount of the silver nitrate (AgNO₃) aqueous solution increases, black stripes can be observed in the solution. As the addition amount of the silver nitrate (AgNO₃) aqueous solution increases further, the color changes from yellow to dark yellow to violet to gray. This color change results from interparticle aggregation. Thus, for synthesis of a silver nanoparticle of desired size, it is important to add an adequate amount of the silver nitrate aqueous solution, which can be monitored with the solution color.

The yellow silver nanoparticle solution exhibits color change with time due to interparticle aggregation. Accordingly, the synthesized silver nanoparticle needs to be used as soon as possible.

### Preparation Example 2

### Preparation Silver (Ag) Nanowire

A silver nanowire is synthesized by reducing silver nitrate (AgNO₃) with ethylene glycol in a mixture of Pt seed and PVP. This method is called a polyol process. According to a commonly employed synthesis method, 5 mL of ethylene glycol is added to a round-bottomed flask equipped with a condenser, a temperature controller and a magnetic stirring bar and refluxed at 160° C. for 120 minutes.

0.5 mL of PtCl₂ solution (1.5×10⁻³ M in ethylene glycol) is added to the heated ethylene glycol. 4 minutes later, 2.5 mL AgNO₃ solution (0.12 M in ethylene glycol) and 5 mL PVP solution (0.36 M in ethylene glycol) are simultaneously injected to the hot mixture solution for 6 minutes using a basic syringe pump. Subsequently, the reaction mixture is further refluxed at 160° C. for 6 minutes. A silver nanowire is grown by reducing AgNO₃ through vigorous magnetic stirring. The product is purified by centrifugation. The reaction mixture is diluted with acetone and phase-separated by centrifugation for 15 minutes at 4000 rpm.

The supernatant containing the silver particle can be easily recovered using a pipette. The centrifugation process is repeated several times until the supernatant becomes colorless.

### Examples 1-3

### Fabrication of Organic Photovoltaic Cell Device Using Silver Nanoparticle

First, a glass substrate on which a thin indium tin oxide (ITO) film is deposited is prepared. Then, a polymer (PEIE, polyethylenimine ethoxylated) is coated using a spin coater at 6000 rpm for 40 seconds. After drying at 110° C. for 10 minutes, the resultant is used as a reference device. To fabricate a solar cell device including a Ag nanoparticle (NP), Ag NPs are mixed at various ratios in a polymer (PEIE, polyethylenimine ethoxylated). 0.1 g, 0.3 g and 0.5 g of Ag NP is mixed with 1 mL of the polymer (PEIE, polyethylenimine ethoxylated) such that the weight ratio of the polymer (PEIE, polyethylenimine ethoxylated) to the Ag NP is about 10:1, 10:3 and 2:1, respectively.

The polymer (PEIE, polyethylenimine ethoxylated) mixed with the Ag NP is coated using a spin coater at 4500 rpm for 40 seconds and then dried at 110° C. for 10 minutes. For active layer coating, a 1:1 mixture of P3HT:PC₆₀BM in 1,2-dichlorobenzene (DCB) is prepared. 20 mg of P3HT and 20 mg of PCBM are mixed at a weight ratio of 1:1 and 1 mL of 1,2-dichlorobenzene (DCB) is added thereto.

The prepared mixture solution is coated on the previously prepared ITO/glass substrate coated with the polymer (PEIE, polyethylenimine ethoxylated) or the polymer-Ag NP as an active layer using a spin coater at 1000 rpm for 40 seconds. On the active layer (P3HT:PC₆₀BM)-coated ITO/glass substrate, molybdenum oxide (MoO₃) and aluminum (Al) are deposited as an electrode by thermal evaporation. Molybdenum oxide (MoO₃) is deposited to a thickness of 10 nm and aluminum (Al) is deposited to a thickness of 80 nm. After the deposition, a solar cell device including a silver nanoparticle is completed by drying at 150° C. for 10 minutes.

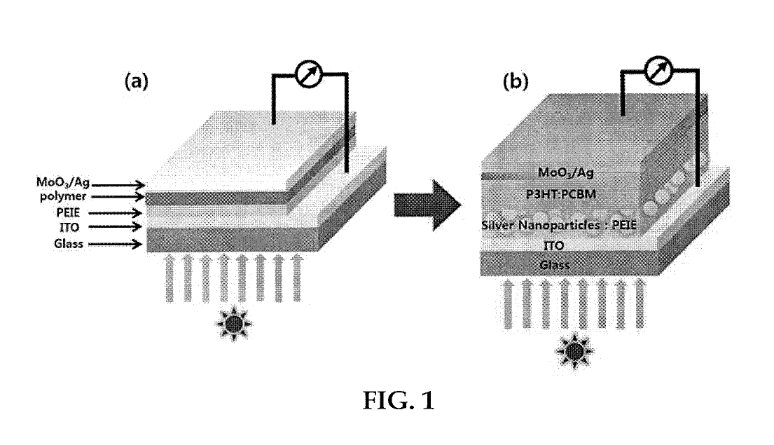

FIG. 1 schematically shows a cross-sectional structure of the fabricated solar cell device including the silver nanoparticle. In FIG. 1, (a) shows the structure of an existing solar cell device wherein only PEIE is used without using a silver nanoparticle and (b) shows the structure of a solar cell fabricated in Examples 1-3.

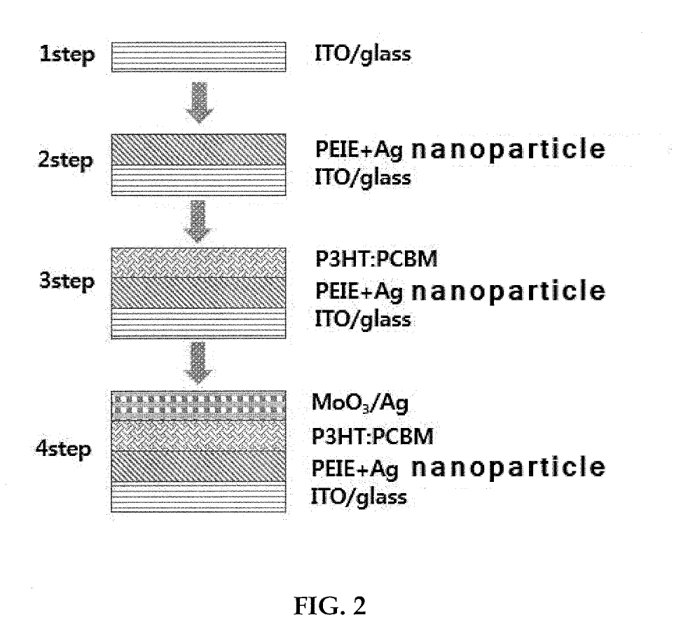

FIG. 2 briefly describes the process of forming layers in fabricating the solar cell according to the present invention.

### Examples 4-7

### Fabrication of Organic Photovoltaic Cell Device Using Silver Nanowire

A glass substrate on which a thin indium tin oxide (ITO) film is deposited is prepared. Then, a polymer (PEIE) is coated using a spin coater at 6000 rpm for 40 seconds. After drying at 110° C. for 10 minutes, the resultant is used as a reference device. To fabricate a solar cell device including a Ag nanowire (NW), Ag NWs are mixed at various ratios in a polymer (PEIE). 0.1 mL of Ag NW is mixed with 1 mL of the polymer (PEIE) such that the weight ratio of the polymer (PEIE) to the Ag NW is 10:1 and the coating thickness is controlled with the spin coating rpm. The polymer (PEIE) mixed with the Ag NW is coated using a spin coater at 5000 rpm, 4000 rpm, 3000 rpm or 2000 rpm for 40 seconds and then dried at 110° C. for 10 minutes. For active layer coating, a 1:1 mixture of P3HT:PC₆₀BM in 1,2-dichlorobenzene (DCB) is prepared. 20 mg of P3HT and 20 mg of PCBM are mixed at a weight ratio of 1:1 and 1 mL of 1,2-dichlorobenzene (DCB) is added thereto.

The prepared mixture solution is coated on the previously prepared ITO/glass substrate coated with the polymer (PEIE) or the polymer-Ag NW as an active layer using a spin coater at 1000 rpm for 40 seconds. On the active layer (P3HT:PC₆₀BM)-coated ITO/glass substrate, molybdenum oxide (MoO₃) and aluminum (Al) are deposited as an electrode by thermal evaporation. Molybdenum oxide (MoO₃) is deposited to a thickness of 10 nm and aluminum (Al) is deposited to a thickness of 80 nm. After the deposition, a solar cell device including a silver nanoparticle is completed by drying at 150° C. for 10 minutes.

### Test Example 1

### Mechanism of Solar Cell Device Using Induced Dipole Polymer and Silver Nanoparticle (Silver Nanowire)

Two types of reverse organic solar cells were fabricated using an induced dipole polymer (PEIE) and a silver nanoparticle or an induced dipole polymer (PEIE) and a silver nanowire in the same manner and under the same condition as Examples 1 and 4.

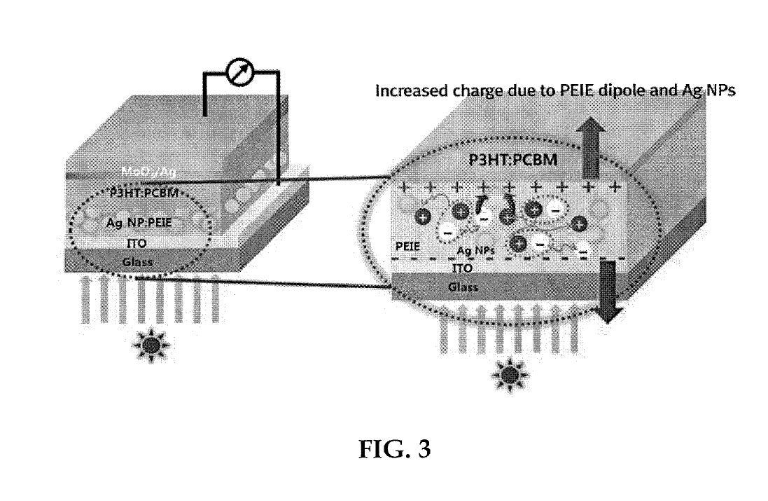

FIG. 3 schematically describes a mechanism by which a plasmon is formed from an induced dipole polymer-metal nanoparticle hybrid layer of the organic photovoltaic cell including the induced dipole polymer (PETE) and the metal (silver) nanoparticle. The figure shows that the transport of holes and electrons in the induced dipole polymer-metal nanoparticle hybrid layer is maximized due to activation by the plasmon effect.

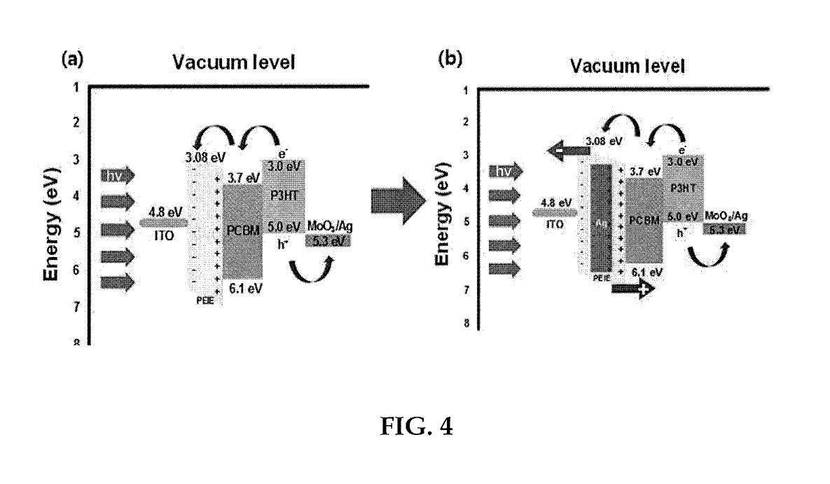

FIG. 4 shows a band diagram of the organic photovoltaic cell device fabricated in Example 1. When compared with the band diagram of an existing solar cell having a single layer of an induced dipole polymer (a), the solar cell device fabricated in Example 1 using the induced dipole polymer-metal nanoparticle hybrid (b) shows a different band diagram due to the surface plasmon effect. This result suggests that the solar cell device of Example 1 exhibits greatly activated hole and electron transport as compared to the existing solar cell device.

### Test Example 2

### Characterization of Solar Cell Device Using Induced Dipole Polymer and Silver Nanoparticle (Silver Nanowire)

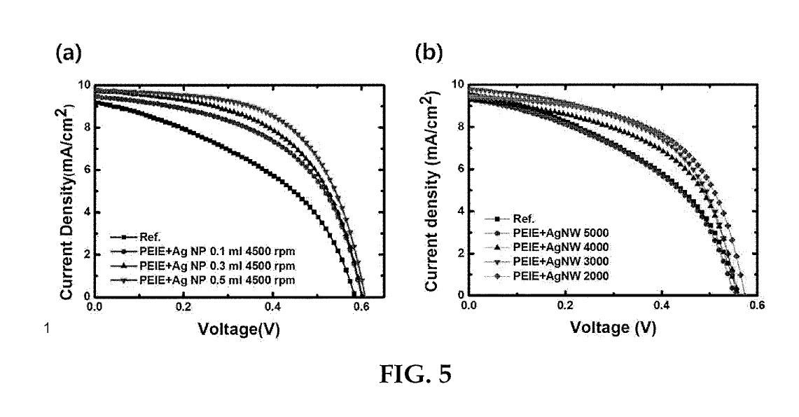

FIG. 5 compares the performance of the organic photovoltaic cell devices fabricated in Examples 1-7 with that of the existing solar cell (Ref.) fabricated using only PEIE.

In FIG. 5, (a) compares the current density-voltage (J-V) characteristics of the organic photovoltaic cells fabricated in Examples 1-3 using the silver nanoparticle with that of the existing solar cell and (b) compares the current density-voltage (J-V) characteristics of the organic photovoltaic cells fabricated in Examples 4-7 using the silver nanowire with that of the existing solar cell.

### Test Example 3

### Comparison of Physical Properties of Solar Cell Devices Using Induced Dipole Polymer and Silver Nanoparticle (Silver Nanowire)

Open-circuit voltage (V_{oc}), short-circuit current density (J_{sc}), fill factor (FF) and photoconversion efficiency (PCE) of the organic photovoltaic cells fabricated in Examples 1-7 are compared with those of the existing solar cell (Ref.) in Table 1.

TABLE 1

| | V_{oc}[V] | J_{sc}[mA/cm²] | FF[%] | PCE[%] |
|---|---|---|---|---|
| Ag NPs | | | | |
| Ref. (PEIE) | 0.58 | 9.16 | 43.00 | 2.30 |
| Ag NP 0.1 ml + | 0.60 | 9.45 | 52.78 | 2.99 |
| PEIE 1 ml | | | | |
| (4500 rpm) | | | | |
| Ag NP 0.3 ml + | 0.60 | 9.71 | 54.74 | 3.19 |
| PEIE 1 ml | | | | |
| (4500 rpm) | | | | |
| Ag NP 0.5 ml + | 0.61 | 9.76 | 59.39 | 3.52 |
| PEIE 1 ml | | | | |
| (4500 rpm) | | | | |
| Ag NWs | | | | |
| Ref. (PEIE) | 0.55 | 9.7 | 43.3 | 2.3 |
| Ag NW 0.1 mL + | 0.55 | 9.3 | 45.0 | 2.3 |
| PEIE 1 mL | | | | |
| (5000 rpm) | | | | |
| Ag NW 0.1 mL + | 0.56 | 9.2 | 53.6 | 2.8 |
| PEIE 1 mL | | | | |
| (4000 rpm) | | | | |
| Ag NW 0.1 mL + | 0.56 | 9.8 | 55.0 | 3.0 |
| PEIE 1 mL | | | | |
| (3000 rpm) | | | | |
| Ag NW 0.1 mL + | 0.57 | 9.4 | 57.2 | 3.1 |
| PEIE 1 mL | | | | |
| (2000 rpm) | | | | |

From Table 1, it can be seen that the organic photovoltaic cells of Examples 1-7 fabricated using the hybrid of the silver nanoparticle or silver nanowire and the induced dipole polymer (PEIE) exhibit 50% or better solar cell efficiency as compared to the existing solar cell device fabricated using the induced dipole polymer (PEIE) without the silver nanoparticle (Ref.), due to increased electron transport ability because of surface plasmon effect and increased possibility of charge recombination. Accordingly, a photoactive layer for improving photocurrent efficiency can be fabricated easily.

The following characteristics have been identified.

In the high-efficiency organic photovoltaic cell using the surface plasmon effect of the induced dipole polymer-metal nanoparticle hybrid according to the present invention, an exciton which is a pair of an electron and a hole is formed in a hole acceptor upon photoexcitation. The exciton is separated into an electron and a hole at the interface between the hole acceptor and an electron acceptor due to the difference in electron affinity of the two materials. The separated electron moves toward a negative electrode through the electron acceptor and the hole moves toward a positive electrode through the hole acceptor due to built-in electric field. Since the electron hops between the electron acceptors, its speed is low and the photocurrent is limited.

Therefore, in the organic photovoltaic cell according to the present invention, a layer is constructed with a hybrid of an induced dipole polymer having a large slope in the flat band shift and thus facilitating charge transport and a silver nanoparticle exhibiting superior plasmon property. As a result, surface plasmon resonance occurs at the interface between the induced dipole polymer and the metal nanoparticle and energy efficiency can be enhanced due to excitation of electron-hole (exciton) in the active layer through dispersion occurring between the metal nanoparticles as compared to the existing solar cell using only the induced dipole polymer or the metal nanoparticle.

In particular, the improvement in photoelectric efficiency is achieved by using the hybrid of the induced dipole polymer and the metal nanoparticle mixed at a specific ratio, not by simply using the induced dipole polymer and the metal nanoparticle.

The high-efficiency organic photovoltaic cell using the surface plasmon effect of the induced dipole polymer-metal nanoparticle hybrid according to the present invention is widely applicable as various solar cell devices and, particularly, is industrially applicable to inexpensive thin-film, large-area devices due to very superior efficiency and economy.

Especially, the organic photovoltaic cell of the present invention device can reduce processing cost because fabrication of flexible devices is possible via a roll-to-roll process.

What is claimed is:

1. An organic photovoltaic cell having a charge transport layer comprising an induced dipole polymer and a metal nanoparticle exhibiting surface plasmon property at a weight ratio from 1:0.1 to 1:1 on a conductive transparent electrode.

2. The organic photovoltaic cell according to claim 1, wherein the induced dipole polymer is polyethylenimine (PEI) or polyethylenimine-ethoxylated (PEIE).

3. The organic photovoltaic cell according to claim 1, wherein the metal nanoparticle is one or more meal selected from Ag, Pt and Au.

4. The organic photovoltaic cell according to claim 1, wherein the metal nanoparticle is a silver nanoparticle or a silver nanowire.

5. A method for fabricating an organic photovoltaic cell, comprising:
mixing an induced dipole polymer and a metal nanoparticle at a weight ratio from 1:0.1 to 1:1;
coating the resulting mixture of the induced dipole polymer and the metal nanoparticle on an ITO substrate;
coating a polymer solar cell material on the mixture of the induced dipole polymer and the metal nanoparticle;
coating molybdenum oxide (MoO₃) on the polymer solar cell material; and
forming a metal electrode.

6. The method for fabricating an organic photovoltaic cell according to claim 5, wherein the mixture of the induced dipole polymer and the metal nanoparticle is spin coated at 1500-6000 rpm.
